(19) United States
(12) Patent Application Publication
(10) Pub. No.: US 2024/0349611 A1
(43) Pub. Date: Oct. 17, 2024

(54) PIEZOELECTRIC ELEMENT

(71) Applicants: DENSO CORPORATION, Kariya-city (JP); TOYOTA JIDOSHA KABUSHIKI KAISHA, Toyota-shi (JP); MIRISE Technologies Corporation, Nisshin-shi (JP); Nisshinbo Micro Devices Inc., Tokyo (JP)

(72) Inventors: YUYA SAKURAI, Nisshin-shi (JP); HIDEO YAMADA, Nisshin-shi (JP); NAOKI MASUMOTO, Tokyo (JP); HIROSHI TAKAHASHI, Tokyo (JP); TAKASHI KAKEFUDA, Tokyo (JP); TAKAHIDE USUI, Tokyo (JP)

(21) Appl. No.: 18/443,624

(22) Filed: Feb. 16, 2024

(30) Foreign Application Priority Data
Apr. 12, 2023 (JP) 2023-064987

(51) Int. Cl. H10N 30/20; H10N 30/50; H10N 30/87

(52) U.S. Cl. CPC H10N 30/2042; H10N 30/503; H10N 30/872

(57) ABSTRACT

A piezoelectric element includes a substrate, a lower electrode arranged on the substrate, a piezoelectric film arranged on the lower electrode, and an upper electrode arranged on the piezoelectric film. Membrane portions are configured by the lower electrode, the piezoelectric film, and the upper electrode, and supported in a cantilever manner on the substrate, due to a recess formed in the substrate and a through hole penetrating the lower electrode, the piezoelectric film, and the upper electrode. At least two of the membrane portions have resonance frequencies different from each other.

### CROSS REFERENCE TO RELATED APPLICATION

This application is based on Japanese Patent Application No. 2023-064987 filed on Apr. 12, 2023, the disclosure of which is incorporated herein by reference.

### TECHNICAL FIELD

The present disclosure relates to a piezoelectric element.

### BACKGROUND

A piezoelectric element used as a microphone or the like includes a substrate, a lower electrode, a piezoelectric film, and an upper electrode stacked on the substrate. A part of the substrate is removed, and a slit is formed to pass through the lower electrode, the piezoelectric film, and the upper electrode, so that the lower electrode, the piezoelectric film, and the upper electrode define a membrane portion cantilevered by the substrate.

### SUMMARY

According to an aspect of the present disclosure, a piezoelectric element includes a substrate, a lower electrode arranged on the substrate, a piezoelectric film arranged on the lower electrode, and an upper electrode arranged on the piezoelectric film. The substrate has a recess formed in the substrate opposite to the lower electrode. A through hole is defined to pass through the lower electrode, the piezoelectric film, and the upper electrode. The recess and the through hole define a plurality of membrane portions configured by the lower electrode, the piezoelectric film, and the upper electrode and cantilevered on the substrate. At least two of the membrane portions have resonance frequencies different from each other.

### BRIEF DESCRIPTION OF DRAWINGS

FIG. 1 is a top view of a piezoelectric element according to a first embodiment.

FIG. 2 is a cross-sectional view taken along line II-II of FIG. 1.

FIG. 3 is a top view of a comparative example.

FIG. 4 is a top view of a piezoelectric element according to a second embodiment.

FIG. 5 is a top view of a piezoelectric element according to a third embodiment.

FIG. 6 is a diagram illustrating a resonance peak of a comparative example.

FIG. 7 is a diagram illustrating a resonance peak according to the third embodiment.

FIG. 8 is a graph illustrating a relationship between a tip width and a difference in resonance frequency.

FIG. 9 is a graph illustrating a relationship between a tip width and

sensitivity.

FIG. 10 is a top view of a piezoelectric element according to a fourth embodiment.

FIG. 11 is a top view of a piezoelectric element according to a fifth embodiment.

FIG. 12 is a top view of a piezoelectric element according to a sixth embodiment.

FIG. 13 is a top view of a piezoelectric element according to a seventh embodiment.

FIG. 14 is a top view of a piezoelectric element according to an eighth embodiment.

### DETAILED DESCRIPTION

A piezoelectric element used as a microphone or the like includes a substrate, a lower electrode, a piezoelectric film, and an upper electrode stacked on one another. A part of the substrate is removed, and a slit penetrates the lower electrode, the piezoelectric film, and the upper electrode, so that the lower electrode, the piezoelectric film, and the upper electrode define a membrane portion cantilevered by the substrate. In such a piezoelectric element, when the membrane portion warps upward or downward due to the residual stress, a gap between the membrane portion and a support portion supported by the substrate increases, and there is a concern that sensitivity may decrease.

For example, a MEMS transducer includes four membrane portions having the same triangular shape with a tip end opposite to a fixed end. The four membrane portions are arranged adjacent to each other so that the tip ends are gathered at one position. When the membrane portion is deformed due to a residual stress, the adjacent membrane portions are also deformed in the same manner. In this case, the enlargement of the gap between the membrane portions is suppressed, and the decrease in sensitivity is suppressed.

However, when the membrane portions have the same shape, the resonance frequencies of the membrane portions are equal to each other. The resonance is strengthened by the membrane portions, and the intensity of the resonance peak is increased. In this case, the resonance peak may become noise. Therefore, it is necessary to reduce the intensity of the resonance peak.

The present disclosure provides a piezoelectric element capable of reducing the intensity of a resonance peak.

According to an aspect of the present disclosure, a piezoelectric element includes a substrate, a lower electrode arranged on the substrate, a piezoelectric film arranged on the lower electrode, and an upper electrode arranged on the piezoelectric film. The substrate has a recess formed in the substrate opposite to the lower electrode, and a through hole passes through the lower electrode, the piezoelectric film, and the upper electrode. The recess and the through hole define membrane portions configured by the lower electrode, the piezoelectric film, and the upper electrode and cantilevered on the substrate. At least two of the membrane portions have resonance frequencies different from each other.

Accordingly, since the at least two membrane portions have different resonance frequencies, the resonance peaks are dispersed, and the intensity of resonance peak in the entire piezoelectric element can be reduced.

Embodiments will be described with reference to the drawings. In the following embodiments, the same or equivalent parts are denoted by the same reference numerals as each other.

### First Embodiment

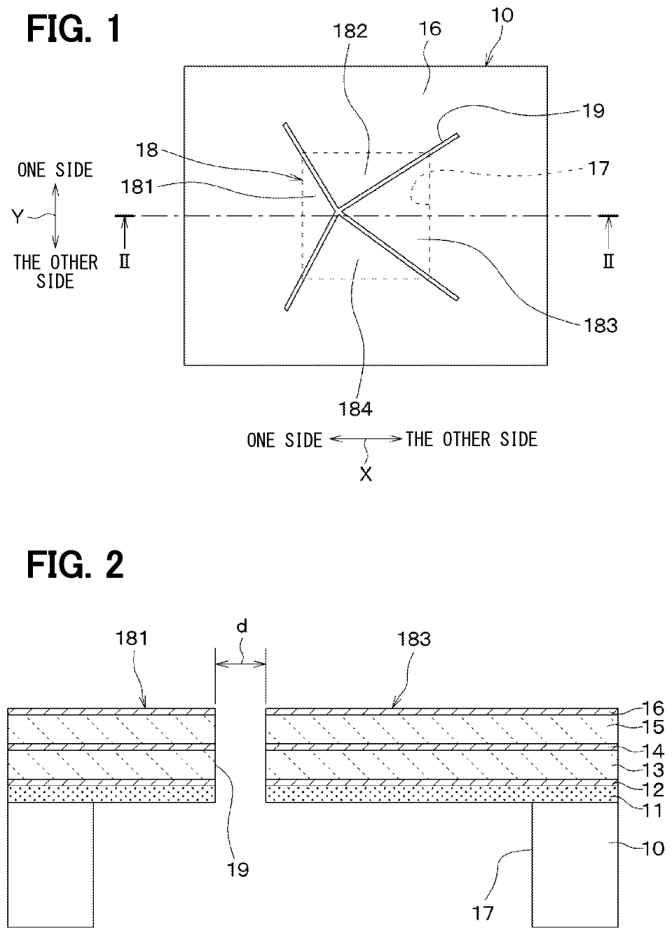

A first embodiment is described below. A piezoelectric element of the present embodiment is used as a microphone. As shown in FIGS. 1 and 2, the piezoelectric element includes a substrate 10, an insulating film 11, a lower electrode 12, a first piezoelectric film 13, an intermediate electrode 14, a second piezoelectric film 15, and an upper electrode 16. The substrate 10 is made of, for example, silicon (Si). The insulating film 11 is arranged on the upper surface of the substrate 10. The insulating film 11 is formed of, for example, a silicon oxide film (SiO₂).

The lower electrode 12, the first piezoelectric film 13, the intermediate electrode 14, the second piezoelectric film 15, and the upper electrode 16 are sequentially stacked on the upper surface of the insulating film 11. The lower electrode 12, the intermediate electrode 14, and the upper electrode 16 are made of a conductive metal such as molybdenum (Mo). The first piezoelectric film 13 and the second piezoelectric film 15 are formed of, for example, lead-free piezoelectric ceramics such as scandium aluminum nitride (ScAlN) and aluminum nitride (AlN). The first piezoelectric film 13 and the second piezoelectric film 15 are made of lead zirconate titanate (PZT) or the like.

A recess 17 is formed in the substrate 10. The recess 17 is formed so as to expose the lower surface of the insulating film 11 adjacent to the substrate 10 by removing a part of the substrate 10. Two directions parallel to the upper surface of the substrate 10 and perpendicular to each other are defined as an X direction and a Y direction, respectively. The recess 17 is opened in a quadrangular shape including two sides parallel to the X direction and two sides parallel to the Y direction on the lower surface of the substrate 10. Since the substrate 10 is removed by the recess 17, a part of the piezoelectric element is thinned. This thinned portion is referred to as a membrane portion 18.

The membrane portion 18 has a through hole 19 that penetrates the insulating film 11, the lower electrode 12, the first piezoelectric film 13, the intermediate electrode 14, the second piezoelectric film 15, and the upper electrode 16. The through hole 19 may have a slit shape. As shown in FIG. 1, the through hole 19 extends from the inner peripheral portion of the recess 17 toward each of the corners, and divides the recess 17 into four areas having a triangular shape. By forming the through hole 19, the stacked body of the insulating film 11, the lower electrode 12, the first piezoelectric film 13, the intermediate electrode 14, the second piezoelectric film 15, and the upper electrode 16 is cantilevered by the substrate 10 at the open end of the recess 17. The stacked body includes the membrane portion 18.

The four divided areas of the membrane portions 18 are referred to as first to fourth membrane portions 181 to 184. The membrane portion 181 and the membrane portion 183 face each other, and the membrane portion 182 and the membrane portion 184 face each other. Specifically, the membrane portion 181 is located on one side in the X direction with respect to the center of the through hole 19. The membrane portion 183 is located on the other side in the X direction with respect to the center of the through hole 19. The membrane portion 182 is located on one side in the Y direction with respect to the center of the through hole 19. The membrane portion 184 is located on the other side in the Y direction with respect to the center of the through hole 19. The center of the through hole 19 is defined as a point area from which four slits extend toward the corners of the recess 17 respectively.

At least two of the membrane portions 181 to 184 have different resonance frequencies due to a difference in shape. In the present embodiment, the membrane portion 182 and the membrane portion 184 have the same shape, but are different in shape from the membrane portion 181 or the membrane portion 183.

Specifically, the center of the through hole 19 is shifted to one side in the X direction from the center of the recess 17. That is, the length (hereinafter, referred to as a beam length) of the membrane portion 181 from the fixed end to the tip end is shorter than that of the membrane portion 183. The center of the through hole 19 is located at the same position in the Y direction as the center of the recess 17, and the membrane portion 182 and the membrane portion 184 have symmetrical shapes with the same beam length. In the present embodiment, the recess 17 is opened in a square shape on the lower surface of the substrate 10. The membrane portion 181 has the shortest beam length and the membrane portion 183 has the longest beam length. When the resonance frequencies of the membrane portions 181 to 184 are defined as f1 to f4, a formula of f3<f2=f4<f1 is satisfied due to the shapes of the membrane portions 181 to 184.

In such a piezoelectric element, in case where a sound pressure is applied to the membrane portion 18, the membrane portions 181 to 184 vibrates. For example, when the free end of the membrane portion 18 is displaced upward, a tensile stress is generated in the first piezoelectric film 13 and a compressive stress is generated in the second piezoelectric film 15. At this time, the sound pressure is detected by measuring the voltage generated between the lower electrode 12 and the upper electrode 16.

When the distance between the adjacent membrane portions 181 to 184 is large, the sensitivity of the piezoelectric element decreases. Thus, it is desirable to reduce the distance to suppress the decrease in sensitivity. For example, the distance is desirably 1 μm or less. That is, the width in a direction perpendicular to the extending direction of the through hole 19 in the XY plane is preferably 1 μm or less. In addition, the distance between the tip end of the membrane portion 181 and the tip end of the membrane portion 183, that is, the distance “d” shown in FIG. 2 is preferably 1 μm or less. In addition, the distance between the tip end of the membrane portion 182 and the tip end of the membrane portion 184 is preferably 1 μm or less.

The effects of this embodiment are described. In a comparative example shown in FIG. 3, the membrane portions 181 to 184 have the same shape, and the resonance frequencies are equal to each other. In such a configuration, resonance is strengthened by the membrane portions 181 to 184, and the intensity of the resonance peak is increased. In this case, the resonance peak may become noise.

In contrast, according to the present embodiment, the membrane portion 181, the membrane portion 182, and the membrane portion 183 have different resonance frequencies. The membrane portion 181, the membrane portion 184, and the membrane portion 183 have different resonance frequencies. Accordingly, the resonance peak is dispersed. Since the intensity of resonance peak in the entire piezoelectric element can be reduced, noise can be suppressed.

Further, according to the embodiment, it is possible to achieve the following advantageous effects.

(1) The resonance frequencies of the at least two membrane portions are different from each other due to a difference in shape. According to this, since the difference in the resonance frequency can be provided only by the pattern formation, the piezoelectric element can be easily manufactured.

(2) The distance between two adjacent membrane portions is set to 1 μm or less. According to this, it is possible to suppress a decrease in sensitivity of the piezoelectric element.

### Second Embodiment

A second embodiment will be described. The present embodiment is the same as the first embodiment except that the shape of the membrane portions 181 to 184 is changed from the first embodiment. Therefore, only the portions different from the first embodiment will be described.

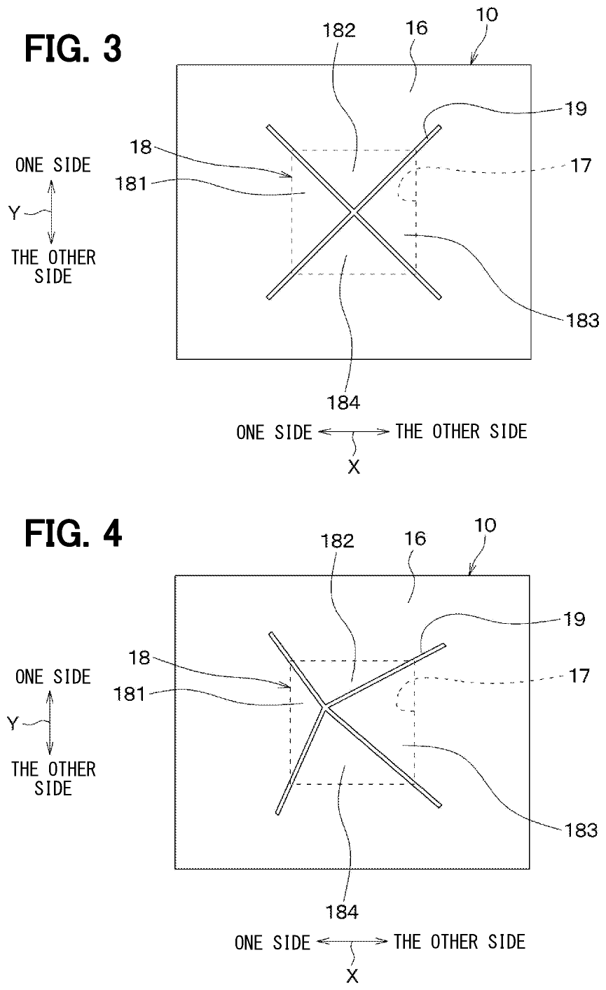

As shown in FIG. 4, in the present embodiment, the center of the through hole 19 is shifted from the center of the recess 17 to one side in the X direction and one side in the Y direction. Accordingly, the beam lengths of the membrane portions 181 to 184 are different from each other, and the resonance frequencies f1 to f4 are different from each other.

In the present embodiment, it is possible to achieve the advantageous effects as similar to the first embodiment with the configuration and operation identical to the first embodiment.

Further, according to the embodiment, it is possible to achieve the following advantageous effects.

(1) All of the four membrane portions 181 to 184 have different resonance frequencies. According to this, since the resonance peak is further dispersed, the intensity of resonance peak can be further reduced.

### Third Embodiment

A third embodiment will be described. The present embodiment is the same as the first embodiment except that the shape of the membrane portion 18 is changed from the first embodiment. Therefore, only the portions different from the first embodiment will be described.

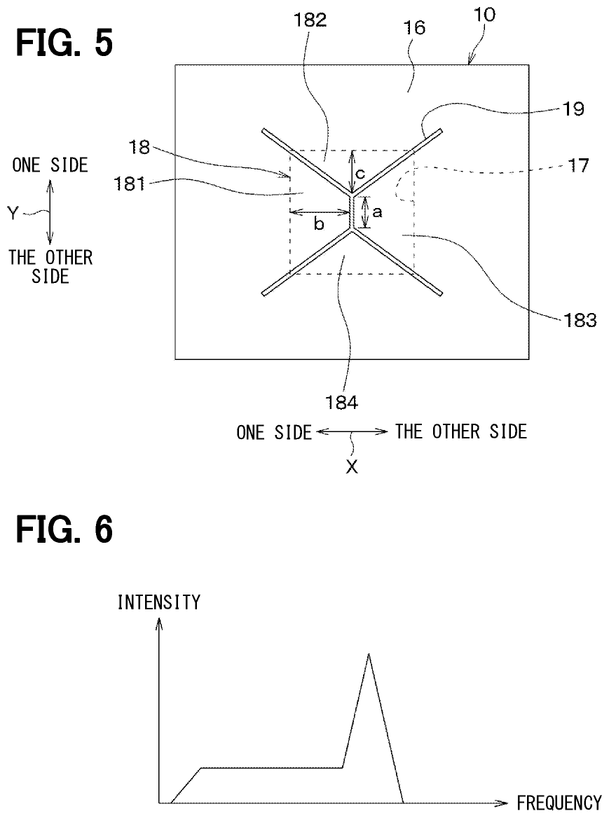

In the present embodiment, two of the membrane portions 181 to 184 have a trapezoidal shape. Specifically, as shown in FIG. 5, the through hole 19 of the present embodiment has a first slit extending from the center of the recess 17 to both sides in the Y direction, and a second slit extending from an end of the first slit toward each corner of the recess 17. As a result, the membrane portion 181 and the membrane portion 183 have a trapezoidal shape in which the fixed side and the tip side are parallel to each other. The membrane portion 181 and the membrane portion 183 have the same shape, and the membrane portion 182 and the membrane portion 184 have the same shape. As a result, f1=f3 and f2-f4 are obtained. The length of the tip side of the membrane portion 181, 183 is referred to as a tip width “a”, the beam length of the membrane portion 181, 183 is referred to as “b”, and the beam length of the membrane portion 182, 184 is referred to as “c”.

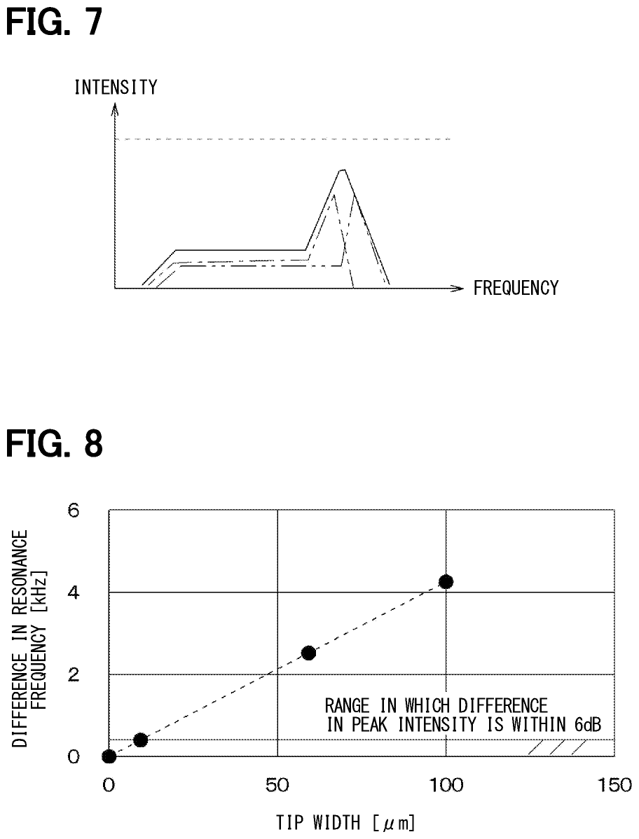

The intensity of resonance peak of the comparative example of FIG. 3 is shown in FIG. 6. The intensity of resonance peak of the present embodiment is shown in FIG. 7. In FIG. 7, the single chain line represents the sum of the vibration intensities of the membrane portions 181 and 183, the double chain line represents the sum of the vibration intensities of the membrane portions 182 and 184, the solid line represents the vibration intensity of the entire piezoelectric element, and the broken line represents the intensity of resonance peak in FIG. 6. As shown in FIG. 7, the intensity of resonance peak of the present embodiment is lower than that of the comparative example.

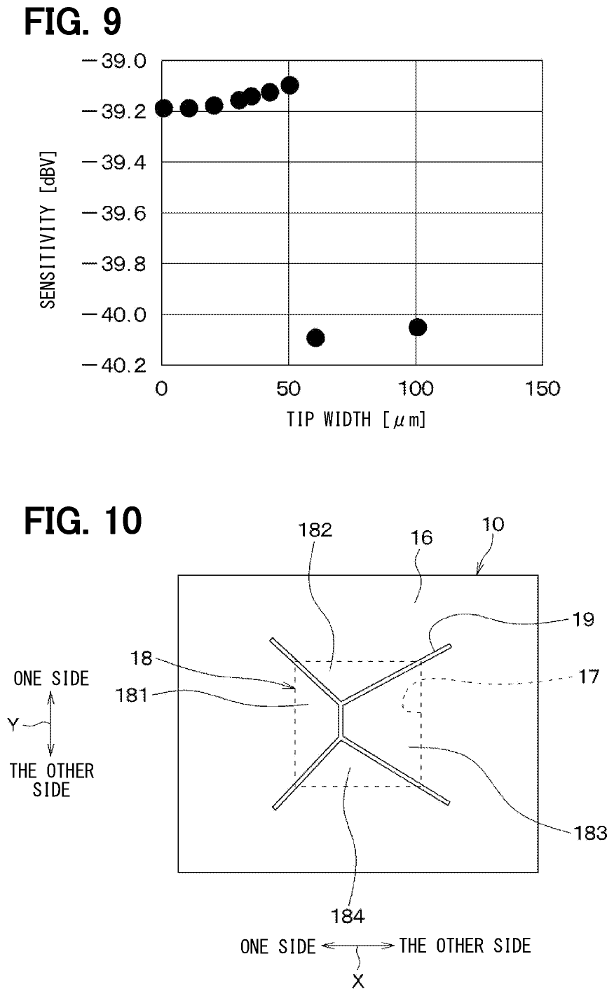

The magnitude at which the resonance peak is reduced varies depending on the tip width “a”. FIGS. 8 and 9 show results of experiments conducted by the present inventors. In this experiment, the beam length “b” was set to 477 μm, the size of the recess 17 was fixed, the tip width “a” was changed, and the resonance frequency and the sensitivity were measured. As shown in FIG. 8, as the tip width “a” increases, the beam length “c” decreases. The difference between f1 (f3) and f2 (f4) increases. This reduces the resonance peak. When the tip width “a” is 10 μm or more, the difference in intensity of resonance peak between the comparative example and the present embodiment is 6 dB or more.

If the tip width “a” is too large, the sensitivity of the piezoelectric element decreases. For example, as shown in FIG. 9, the sensitivity is maintained when the tip width “a” is 50 μm or less, but the sensitivity decreases when the tip width “a” is 60 μm or more. Therefore, in order to suppress a decrease in sensitivity, it is desirable to shorten the tip width “a” to some extent. For example, the tip width “a” is preferably 50 μm or less.

In order to increase the difference between f1 (f3) and f2 (f4), it is preferable that b>c. By making a difference in beam length in addition to the difference in tip width, the difference between f1 (f3) and f2 (f4) is further increased, and the resonance peak is further reduced.

Also in the present embodiment, similarly to the first embodiment, in order to suppress a decrease in sensitivity, it is desirable that the distance between the adjacent membrane portions 181 to 184 be 1 μm or less. Regarding the distance between the membrane portion 181 and the membrane portion 183, it is desirable that the width of the through hole 19 in the X direction, extending from the center of the recess 17 to both sides in the Y direction, is 1 μm or less.

In the present embodiment, it is possible to achieve the advantageous effects as similar to the first embodiment with the configuration and operation identical to the first embodiment.

Further, according to the embodiment, it is possible to achieve the following advantageous effects.

(1) Two of the membrane portions 181 to 184 have a trapezoidal shape. According to this, it is possible to form the entire membrane portion 18 in a highly symmetrical shape and to form a structure in which sound pressure is easily applied uniformly. In addition, by increasing the tip width of the trapezoidal membrane portion 181, 183, it is possible to increase the difference in mass of the tip end portion between the membrane portion 181, 183 and the membrane portion 182, 184. Therefore, it is easy to increase the difference in resonance frequency, and it is easy to reduce the resonance peak. Note that two of the membrane portions 181 to 184 may have a substantially trapezoidal shape instead of a completely trapezoidal shape while the above effect can be obtained. For example, the tip side of the membrane portion 181, 183 may be slightly inclined with respect to the fixed side.

### Fourth Embodiment

A fourth embodiment will be described. The present embodiment is the same as the third embodiment except that the shapes of the membrane portions 181 to 184 are changed from the third embodiment. Therefore, only the portions different from the third embodiment will be described.

As shown in FIG. 10, in the present embodiment, the central portion of the through hole 19 extending to both sides in the Y direction is shifted to one side in the X direction from the center of the recess 17. Accordingly, since f1>f3, the resonance peak is further dispersed, and the intensity of resonance peak of the entire piezoelectric element can be further reduced.

In the present embodiment, it is possible to attain the advantageous effects as similar to the first and third embodiments with the configuration and operation identical to the first and third embodiments.

### Fifth Embodiment

A fifth embodiment will be described. The present embodiment is the same as the third embodiment except that the shape of the recess 17 is changed from that of the third embodiment. Therefore, only the portions different from the third embodiment will be described.

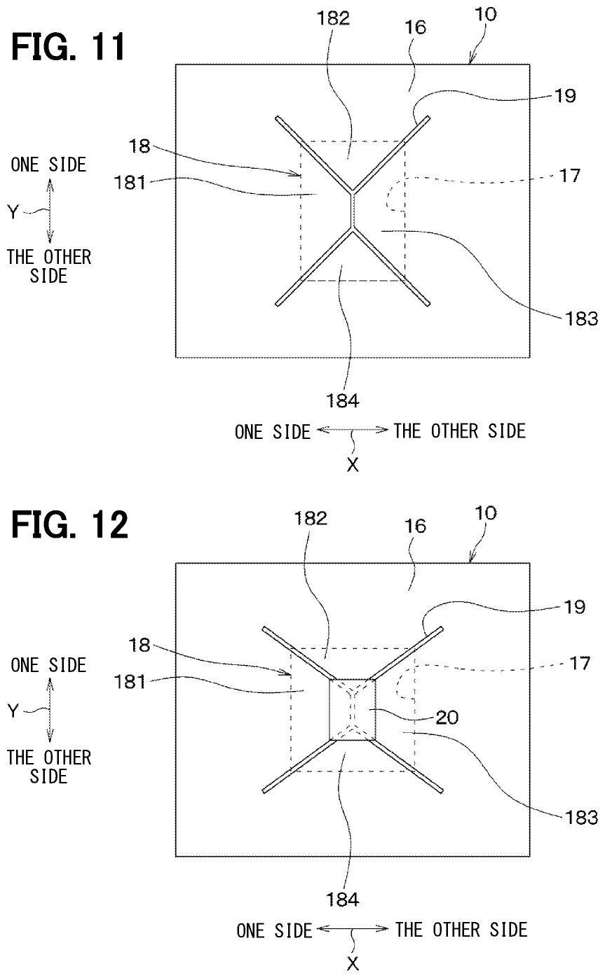

As shown in FIG. 11, the recess 17 of the present embodiment is opened in a rectangular shape with the Y direction as the longitudinal direction. Specifically, the length of the recess 17 in the X direction is shorter than that of the third embodiment, and the length in the Y direction is longer than that of the third embodiment so as to have the same opening area as that of the recess 17 of the third embodiment. Accordingly, the beam lengths of the membrane portion 181 and the membrane portion 183 are shorter than those of the third embodiment.

In order to increase the resonance frequency, the beam length of the membrane portion 181 to 184 may be shortened. For example, the beam lengths of the membrane portion 181 and the membrane portion 183 can be shortened by increasing the width in the X direction of the central portion of the through hole 19 extending to both sides in the Y direction, but there is a risk of sensitivity reduction. In addition, the area on the substrate 10 cannot be effectively utilized.

In contrast, by forming the recess 17 in a rectangular shape as in the present embodiment, the beam length of the membrane portion 181, 183 can be shortened while the width of the through hole 19 is kept narrow. Therefore, it is possible to increase the resonance frequency while suppressing a decrease in sensitivity and efficiently utilizing the area on the substrate 10.

In the present embodiment, it is possible to attain the advantageous effects as similar to the first and third embodiments with the configuration and operation identical to the first and third embodiments.

### Sixth Embodiment

A sixth embodiment will be described. The present embodiment is the same as the third embodiment except that a low Young's modulus film is added to the third embodiment. Therefore, only a portion different from the third embodiment will be described.

As shown in FIG. 12, the piezoelectric element of the present embodiment includes a low Young's modulus film 20. The low Young's modulus film 20 is made of a material having a Young's modulus lower than that of the membrane portion 18. For example, the low Young's modulus film 20 is made of polyimide. The low Young's modulus film 20 has an upper surface in a rectangular shape with the Y direction as the longitudinal direction, and covers from the upper side and connects the tip ends of the membrane portions 181 to 184 to each other.

In the present embodiment, it is possible to attain the advantageous effects as similar to the first and third embodiments with the configuration and operation identical to the first and third embodiments.

Further, according to the embodiment, it is possible to achieve the following advantageous effects.

(1) The low Young's modulus film 20 covering the membrane portions 181 to 184 is provided. According to this, when a part of the membrane portion 181 to 184 resonates and the other membrane portion does not resonate, the displacement of the resonating membrane portion can be reduced by the low Young's modulus film 20. Therefore, the intensity of resonance peak can be further reduced.

### Seventh Embodiment

A seventh embodiment will be described. The present embodiment is the same as the first embodiment except that a weight portion is added to the first embodiment, and thus only portions different from the first embodiment will be described.

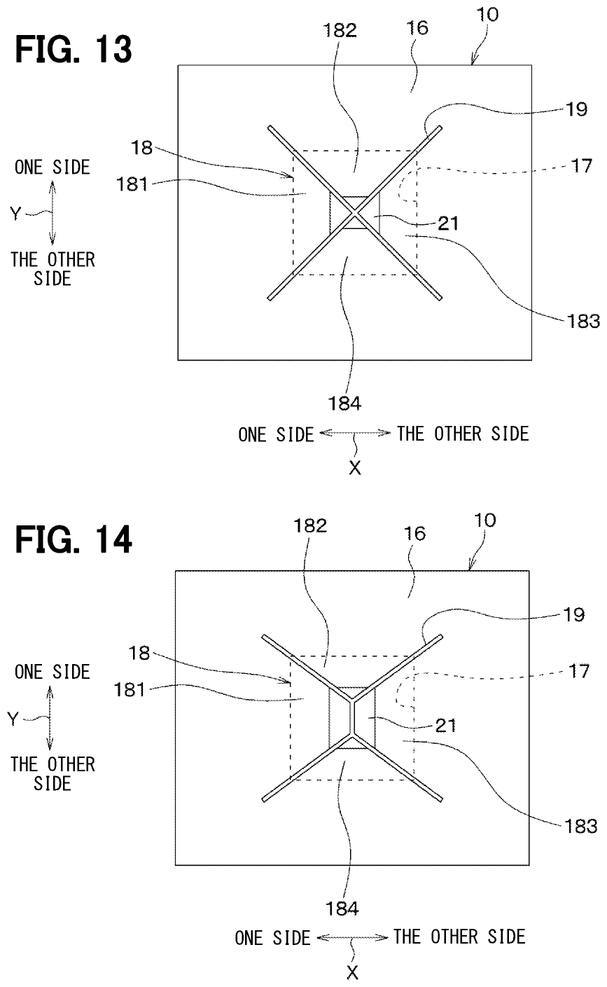

In the present embodiment, the membrane portions 181 to 184 have different resonance frequencies due to a difference in mass. Specifically, as shown in FIG. 13, in the present embodiment, the center of the through hole 19 overlaps the center of the recess 17, and the upper surfaces of the membrane portions 181 to 184 have the same shape. The membrane portion 18 includes a weight portion 21. The weight portion 21 is arranged on the upper surface of the upper electrode 16 and is made of titanium, aluminum, molybdenum, or the like. The weight portion 21 is formed at the tip end of the upper electrode 16 in each of the membrane portions 181 to 184. The weight portions 21 formed on the upper electrode 16 of the membrane portions 181 to 184 are respectively referred to as weight portions 211 to 214.

The upper surface of each of the weight portions 211 to 214 has a triangular shape having a side parallel to the fixed end of the membrane portion 181 to 184 and two sides along the open end of the through hole 19. The weight portions 211 to 214 are made of the same material and have the same thickness. The area of the upper surface of the weight portion 211, 213 is larger than that of the weight portion 212, 214, and the mass of the membrane portion 181, 183 is larger than that of the membrane portion 182, 184. Thus, a formula of f1=f3<f2=f4 is satisfied.

In the present embodiment, it is possible to achieve the advantageous effects as similar to the first embodiment with the configuration and operation identical to the first embodiment.

Further, according to the embodiment, it is possible to achieve the following advantageous effects.

(1) The membrane portions 181 to 184 have different resonance frequencies due to a difference in mass. According to this, even in a highly symmetric structure in which the upper surface of the membrane portions 181 to 184 have the same shape, it is possible to disperse the resonance peak and reduce the resonance peak intensity.

### Eighth Embodiment

An eighth embodiment will be described hereafter. The present embodiment is the same as the third embodiment except that the weight portion 21 is added to the third embodiment. Therefore, only a portion different from the third embodiment will be described.

In the seventh embodiment, the shape of the membrane portions 181 to 184 is changed from that in the first embodiment, and the weight portion 21 is added. As shown in FIG. 14, the weight portion 21 may be added to the third embodiment. In the weight portion 21 of the present embodiment, the weight portions 211 and 213 are formed in a trapezoidal shape and the weight portions 212 and 214 are formed in a triangular shape so as to have a rectangular shape as a whole.

In the present embodiment in which the membrane portion 181, 183 has a trapezoidal shape, the tip end portion of the membrane portion 181, 183 is wider than the membrane portion 182, 184. Therefore, when the weight portion 21 is formed in a rectangular shape that is easy to form, a large mass difference can be provided between the membrane portion 181, 183 and the membrane portion 182, 184, and the difference in resonance frequency can be increased.

In the present embodiment, it is possible to attain the advantageous effects as similar to the effects in the first and third embodiments with the configuration and operation identical to the ones in the first and third embodiments.

### OTHER EMBODIMENTS

The present disclosure is not limited to the embodiments described above, and can be appropriately modified within the scope described in the claims. Individual elements or features of a particular embodiment are generally not limited to that particular embodiment, but, where applicable, are interchangeable and can be used in a selected embodiment, even if not specifically shown or described. Further, in each of the above-mentioned embodiments, it goes without saying that components of the embodiment are not necessarily essential except for a case in which the components are particularly clearly specified as essential components, a case in which the components are clearly considered in principle as essential components, and the like. Further, in each of the embodiments described above, when numerical values such as the number, numerical value, quantity, range, and the like of the constituent elements of the embodiment are referred to, except in the case where the numerical values are expressly indispensable in particular, the case where the numerical values are obviously limited to a specific number in principle, and the like, the present disclosure is not limited to the specific number. Furthermore, a shape, positional relationship or the like of a structural element, which is referred to in the embodiments described above, is not limited to such a shape, positional relationship or the like, unless it is specifically described or obviously necessary to be limited in principle.

The piezoelectric element may not include the intermediate electrode 14.

In the seventh and eighth embodiments, the mass of the membrane portions 181 to 184 differs depending on the weight portion 21, but the mass may differ depending on the material or density of the insulating film 11 to the upper electrode 16 constituting the membrane portions 181 to 184. In addition, a difference in mass may be provided depending on the material, density, and thickness of the weight portion 21.

The membrane portions 181 to 184 may have different resonance frequencies due to a difference in Young's modulus. For example, a difference in Young's modulus can be provided by changing the material of the lower electrode 12 to the upper electrode 16 among the membrane portions 181 to 184.

A difference in resonance frequency may be provided by combining a difference in shape, a difference in mass, and a difference in Young's modulus of the membrane portions 181 to 184.

In the first, second, fourth, and fifth embodiments, the low Young's modulus film 20 of the sixth embodiment may be provided. In the second and fourth to sixth embodiments, the weight portion 21 of the seventh and eighth embodiments may be provided.

The low Young's modulus film 20 may cover at least two of the membrane portions 181 to 184 having different resonance frequencies from each other. For example, in the sixth embodiment, the low Young's modulus film 20 may cover only the membrane portion 181, 182.

What is claimed is:

1. A piezoelectric element comprising:
a substrate;
a lower electrode arranged on the substrate;
a piezoelectric film arranged on the lower electrode; and
an upper electrode arranged on the piezoelectric film, wherein
the substrate has a recess formed on a side of the substrate opposite to the lower electrode,
a through hole is defined to pass through the lower electrode, the piezoelectric film, and the upper electrode,
the recess and the through hole define a plurality of membrane portions made of the lower electrode, the piezoelectric film, and the upper electrode, the membrane portions being cantilevered by the substrate, and
at least two of the membrane portions have resonance frequencies different from each other.

2. The piezoelectric element according to claim 1, wherein at least two of the membrane portions have different resonance frequencies due to a difference in shape.

3. The piezoelectric element according to claim 1, wherein at least two of the membrane portions have different resonance frequencies due to a difference in mass.

4. The piezoelectric element according to claim 1, wherein at least two of the membrane portions have different resonance frequencies due to a difference in Young's modulus.

5. The piezoelectric element according to claim 1, wherein two of the membrane portions are shaped in trapezoid.

6. The piezoelectric element according to claim 1, further comprising a film having a Young's modulus lower than that of the membrane portion, wherein
the film covers at least two of the membrane portions.

7. The piezoelectric element according to claim 1, wherein a distance between two of the membrane portions adjacent to each other is 1 μm or less.
